(19) United States
(12) Patent Application Publication
(10) Pub. No.: US 2024/0314469 A1
(43) Pub. Date: Sep. 19, 2024

(54) ANALOG-TO-DIGITAL CONVERTER, IMAGE SENSOR INCLUDING THE SAME, AND CORE AMPLIFIER OF THE ANALOG-TO-DIGITAL CONVERTER

(71) Applicant: SAMSUNG ELECTROICS CO., LTD., Suwon-si (KR)

(72) Inventors: Chanmin PARK, Suwon-si (KR); Sangwoo Kim, Suwon-si (KR); Mira Lee, Suwon-si (KR)

(73) Assignee: SAMSUNG ELECTROICS CO., LTD., Suwon-si (KR)

(21) Appl. No.: 18/606,544

(22) Filed: Mar. 15, 2024

(30) Foreign Application Priority Data
Mar. 17, 2023 (KR) 10-2023-0035394

(51) Int. Cl. H04N 25/772; H03M 1/08

(52) U.S. Cl. CPC H04N 25/772; H03M 1/08

(57) ABSTRACT

An analog-to-digital converter of an image sensor includes a pixel load connected to a column line connected to a plurality of pixels, a pixel signal input terminal configured to receive a pixel signal through the column line, a ramp signal input terminal configured to receive a ramp signal compared with the pixel signal and operating as a source follower, a core amplifier configured to compare the pixel signal with the ramp signal, and output the pixel signal based on a comparison result, and an auto-zero switching unit configured to initialize the core amplifier.

### CROSS-REFERENCE TO RELATED APPLICATION

This application is based on and claims priority under 35 U.S.C. § 119 to Korean Patent Application No. 10-2023-0035394, filed on Mar. 17, 2023, in the Korean Intellectual Property Office, the disclosure of which is incorporated by reference herein in its entirety.

### BACKGROUND

The present disclosure relates to an analog-to-digital converter, an image sensor including the same, and a core amplifier of the analog-to-digital converter, and more particularly, to an analog-to-digital converter including a planar transistor and a fin field-effect transistor (FinFET), an image sensor including the analog-to-digital converter, and a core amplifier of the analog-to-digital converter.

An image sensor is a device that captures a two-dimensional (2D) or three-dimensional (3D) image of an object. An image sensor generates an image of an object by using a photoelectric conversion element that reacts according to the intensity of light reflected from the object. With the recent development of complementary metal-oxide semiconductor (CMOS) technology, CMOS image sensors using CMOS have been widely used.

An image sensor requires an analog-to-digital converter that receives an analog signal and converts the received analog signal into a digital signal. The analog-to-digital converter of the image sensor mainly includes a FinFET. The FinFET has the disadvantages of high thermal noise and high power consumption.

### SUMMARY

Example embodiments provide an analog-to-digital converter of an image sensor having low thermal noise by using a planar transistor and a fin field-effect transistor (FinFET) together.

According to an aspect of an example embodiment, an analog-to-digital converter of an image sensor, includes: a pixel load connected to a column line connected to a plurality of pixels; a pixel signal input terminal configured to receive a pixel signal through the column line; a ramp signal input terminal configured to receive a ramp signal; a core amplifier configured to compare the pixel signal with the ramp signal, and output the pixel signal based on a comparison result; and an auto-zero switching unit configured to initialize the core amplifier, wherein the core amplifier includes: a first comparator configured to compare the pixel signal with the ramp signal, the first comparator including a first transistor and a second transistor; and a second comparator including a third transistor configured to receive an output signal of the first comparator and a fourth transistor configured to amplify the output signal, wherein the first comparator is further configured to receive the pixel signal or the ramp signal through a fin field-effect transistor (FinFET), and each of the first transistor, the second transistor, the third transistor, and the fourth transistor includes a planar transistor.

According to an aspect of an example embodiment, an image sensor includes: a pixel array connected to a plurality of column lines and including a plurality of pixels; and an analog-to-digital converter configured to convert a plurality of pixel signals output through the plurality of column lines, wherein the analog-to-digital converter includes: a pixel load configured to receive a pixel signal from at least one of the plurality of pixels, a pixel signal input terminal configured to select at least one pixel signal, and receive the selected at least one pixel signal, a ramp signal input terminal configured to receive a ramp signal, a core amplifier configured to compare the pixel signal with the ramp signal, and output the pixel signal based on a comparison result, and an auto-zero switching unit configured to perform an initialization operation on the core amplifier, wherein the core amplifier includes: a first comparator including a first transistor and a second transistor configured to compare the pixel signal with the ramp signal, and a second comparator including a third transistor configured to receive an output signal of the first comparator and a fourth transistor configured to amplify the output signal, wherein the first comparator is further configured to receive the pixel signal or the ramp signal through a fin field-effect transistor (FinFET), and each of the first transistor, the second transistor, the third transistor, and the fourth transistor includes a planar transistor.

According to an aspect of an example embodiment, a core amplifier of an analog-to-digital converter of an image sensor, includes: a first comparator configured to compare a pixel signal with a ramp signal, the first comparator including a first transistor and a second transistor; and a second comparator including a third transistor configured to receive an output signal of the first comparator and a fourth transistor configured to amplify the output signal, wherein the first comparator is further configured to receive the pixel signal or the ramp signal through a fin field-effect transistor (FinFET), and each of the first transistor, the second transistor, the third transistor, and the fourth transistor includes a planar transistor.

### BRIEF DESCRIPTION OF THE DRAWINGS

The above and/or other aspects will be more clearly understood from the following detailed description of example embodiments taken in conjunction with the accompanying drawings, in which:

FIG. 1 is a block diagram illustrating an image sensor, according to an embodiment;

FIG. 2 is a block diagram for describing an analog-to-digital converter of an image sensor, according to an embodiment;

FIG. 3 is a circuit diagram illustrating an analog-to-digital converter of an image sensor, according to an embodiment;

FIG. 4A is a view for describing a planar transistor, according to an embodiment;

FIG. 4B is a view for describing a fin field-effect transistor (FinFET), according to an embodiment;

FIG. 5 is a circuit diagram for describing a pixel load of an image sensor, according to an embodiment;

FIG. 6 is a circuit diagram for describing a pixel signal input terminal of an image sensor, according to an embodiment;

FIG. 7 is a circuit diagram for describing a ramp signal input terminal of an image sensor, according to an embodiment;

FIG. 8 is a circuit diagram for describing a core amplifier of an image sensor, according to an embodiment;

FIG. 9 is a timing diagram for describing a method of operating an image sensor, according to an embodiment; and

FIG. 10 is a flowchart for describing a method of operating an image sensor, according to an embodiment.

### DETAILED DESCRIPTION

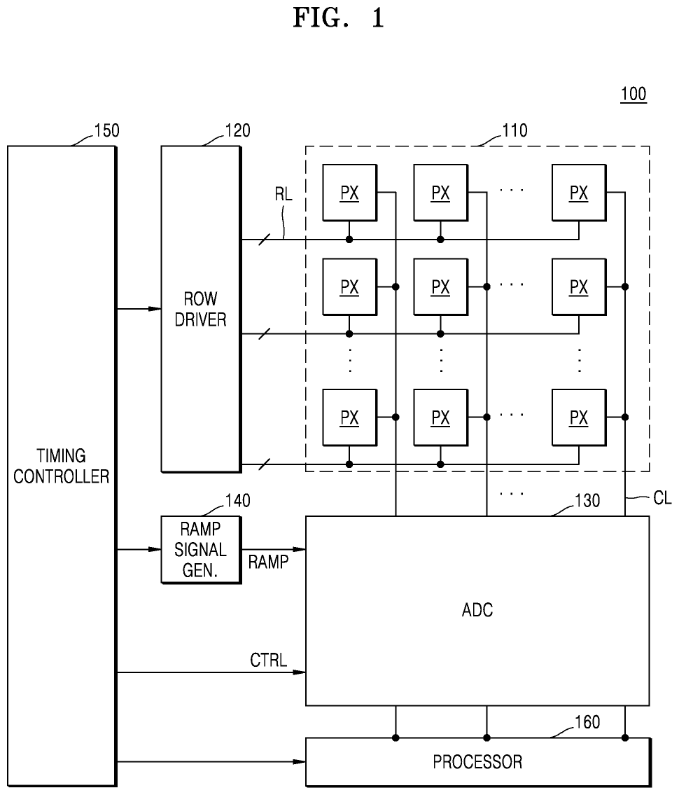

FIG. 1 is a block diagram illustrating an image sensor 100, according to an embodiment.

The image sensor 100 according to an embodiment may be mounted on an electronic device having an image or light sensing function. For example, the image sensor 100 may be mounted on an electronic device such as a camera, a smartphone, a wearable device, an Internet of Things (IoT) device, a tablet personal computer (PC), a personal digital assistant (PDA), a portable multimedia player (PMP), or a navigation device. Also, the image sensor 100 may be mounted on an electronic device provided as a component in a vehicle, furniture, manufacturing equipment, a door, or any of various measurement devices.

The image sensor 100 according to an embodiment may include a pixel array 110, a row driver 120, an analog-to-digital converter (ADC) 130, a ramp signal generator 140, a timing controller 150, and a processor 160.

The pixel array 110 according to an embodiment includes a plurality of pixels PX connected to a plurality of row lines and a plurality of column lines COL and arranged in a matrix. Each of the plurality of pixels PX includes a light sensing element. For example, the light sensing element may include a photodiode, a phototransistor, a photogate, or a pinned photodiode. Each of the plurality of pixels PX may include at least one light sensing element, and according to an embodiment, each of the plurality of pixels may include a plurality of light sensing elements. The plurality of light sensing elements may be stacked on each other.

Each of the plurality of pixels PX according to an embodiment may detect light by using a light sensing element, and may convert the light into a pixel signal that is an electrical signal. Each of the plurality of pixels PX may detect light in a specific spectral region. For example, the plurality of pixels PX may include a red pixel for converting light in a red spectral region into an electrical signal, a green pixel for converting light in a green spectral region into an electrical signal, and a blue pixel for converting light in a blue spectral region into an electrical signal. A color filter through which light in a specific spectral region is transmitted may be located over each of the plurality of pixels PX.

The row driver 120 according to an embodiment drives the pixel array 110 in units of rows. The row driver 120 according to an embodiment may decode a row control signal (e.g., an address signal) generated by the timing controller 150, and may select at least one of the row lines constituting the pixel array 110 in response to the decoded row control signal. For example, the row driver 120 may generate a row selection signal. The pixel array 110 outputs a pixel signal from a row selected by the row selection signal provided from the row driver 120. The pixel signal may include a reset signal and an image signal.

The ADC 130 according to an embodiment converts an analog pixel signal input from the pixel array 110 into a digital signal. The ADC 130 according to an embodiment may include a plurality of comparators. The ADC 130 according to an embodiment may compare a pixel signal output from a unit pixel connected to any one of the column lines COL constituting the pixel array 110 with a ramp signal RAMP. The ADC 130 according to an embodiment may include a plurality of pixel loads provided to respectively correspond to columns.

The ADC 130 according to an embodiment may receive a pixel signal and a ramp signal RAMP generated from the ramp signal generator 140, may compare the pixel signal with the ramp signal, and may output a comparison result signal to an output terminal. The ADC 130 according to an embodiment may generate a comparison result signal to which a correlated double sampling method is applied, and may be referred to as a correlated double sampling circuit. Pixel signals output from the plurality of pixels PX may have a deviation due to unique characteristics of each pixel (e.g., fixed pattern noise (FPN)) and/or a deviation due to a difference in logic characteristics for outputting a pixel signal from the pixel PX. A process of obtaining a reset component (or a reset signal) and an image component (or an image signal) for each pixel signal and extracting a difference between the reset component and the image component as an effective signal component in order to compensate for a deviation between pixel signals is called correlated double sampling. The ADC 130 according to an embodiment may output a comparison result signal to which a correlated double sampling method is applied.

The ADC 130 according to an embodiment may include auto-zero circuits for initializing a plurality of comparators. The ADC 130 according to an embodiment may operate based on a smaller amount of bias current in an auto-zero step than in a comparison step. Accordingly, noise may be reduced and an input range may increase. According to an embodiment, the ADC 130 according to an embodiment may include a limiting circuit that connects an output terminal to a common node, and the limiting circuit may prevent a voltage level of the common node from being lowered below a minimum value and may compensate for a voltage fluctuation occurring at an output node. The ADC 130 according to an embodiment may adaptively control current sources that generate bias current for each operation step, and may generate minimum bias current before and after decision. Accordingly, the ADC 130 according to an embodiment may prevent a power fluctuation according to an operation.

At least one of the comparators included in the ADC 130 according to an embodiment may operate as a counter. A counter control signal CTRL according to an embodiment may include a counter clock signal, a counter reset signal for controlling a reset operation of the comparators, and an inverse signal for inverting internal bits of the plurality of comparators. The ADC 130 according to an embodiment may count a comparison result signal according to the counter clock signal and may output the same as a digital signal.

The ADC 130 according to an embodiment may include an up/down counter and a bitwise inversion counter. In this case, the bitwise counter may perform an operation similar to that of the up/down counter. For example, the bitwise inversion counter may perform a function of performing only up-counting and a function of inverting all bits in the counter to make the bits into 1's complement when a specific signal is input. The bitwise inversion counter may perform reset counting, and may invert a result into 1's complement, that is, a negative value.

The ramp signal generator 140 according to an embodiment may generate a ramp signal. The ramp signal generator 140 according to an embodiment may operate based on a ramp control signal provided from the timing controller 150. The ramp control signal according to an embodiment may include a ramp enable signal and a mode signal. When the ramp enable signal is enabled, the ramp signal generator 140 according to an embodiment may generate a ramp signal having a slope set based on the mode signal.

The timing controller 150 according to an embodiment may control an operation or a timing of each of the row driver 120, the ADC 130, and the ramp signal generator 140 by outputting a control signal or a clock signal to each of the row driver 120, the ADC 130, and the ramp signal generator 140.

The processor 160 according to an embodiment may process data of a plurality of pixel values input from the ADC 130. The processor 160 may perform image compensation, binning, downsizing, etc. on image data. Accordingly, image-processed output image data may be generated and output in certain units.

For example, the processor 160 may process image data according to colors. For example, when image data includes red, green, and blue pixel values, the processor 160 according to an embodiment may process red, green, and blue pixels in parallel or in series. Also, the processor 160 according to an embodiment may perform color-specific processing on image data in parallel, and may include a plurality of processing circuits.

The processor 160 according to an embodiment may generate output image data by processing input image data

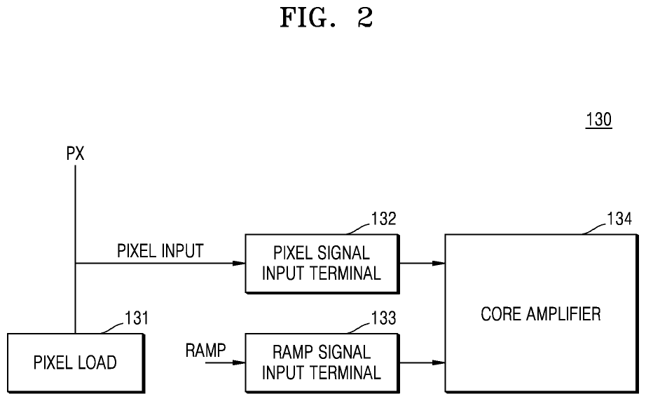

FIG. 2 is a block diagram for describing the ADC 130 of the image sensor 100, according to an embodiment.

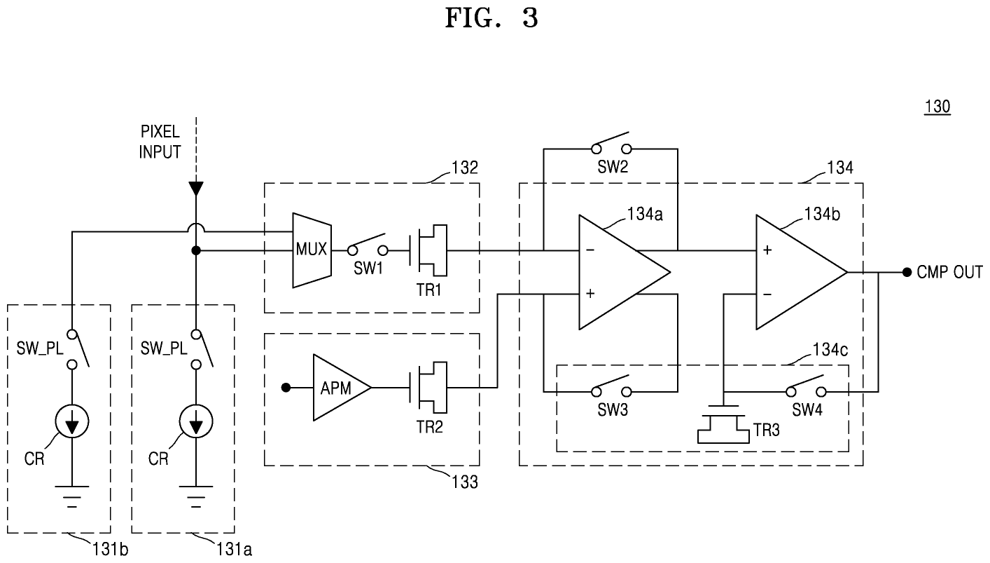

The ADC 130 according to an embodiment may include a pixel load 131, a pixel signal input terminal 132, a ramp signal input terminal 133, and a core amplifier 134. Also, although not shown in FIG. 2, the ADC 130 according to an embodiment may include an auto-zero switching unit that performs an initialization operation on the core amplifier 134. However, as described with reference to FIG. 3, the auto-zero switching unit according to an embodiment may be located in the core amplifier.

The pixel load 131 according to an embodiment may be connected to the plurality of pixels, and may receive a pixel signal Pixel Input from at least one of the plurality of pixels PX. For example, the pixel load 131 may operate as a source follower. The pixel load 131 according to an embodiment may include at least one current source. The at least one current source included in the pixel load 131 according to an embodiment may include a passive current source or an active current source. For example, the pixel load 131 according to an embodiment may include at least one transistor, and may operate as a passive current source. When the pixel load 131 operates as a source follower, at least one pixel PX included in the pixel array 110 of the image sensor 100 according to an embodiment may transmit a pixel signal generated based on a received optical signal to the ADC 130.

The pixel signal input terminal 132 according to an embodiment may select at least one pixel signal Pixel Input, and may receive the selected pixel signal Pixel Input. For example, the pixel signal input terminal 132 may include a multiplexer MUX, and the multiplexer MUX of the pixel signal input terminal 132 may be connected in series to the pixel PX of the pixel array 110. The pixel signal input terminal 132 according to an embodiment may include a plurality of transistors, and each of the plurality of transistors may be a metal oxide semiconductor capacitor (MOSCAP) transistor. When each of the plurality of transistors is a MOSCAP transistor, the pixel signal input terminal 132 according to an embodiment has an input range having a certain range. The input range of the pixel signal input terminal 132 according to an embodiment may vary according to types of the transistors included in the pixel signal input terminal 132.

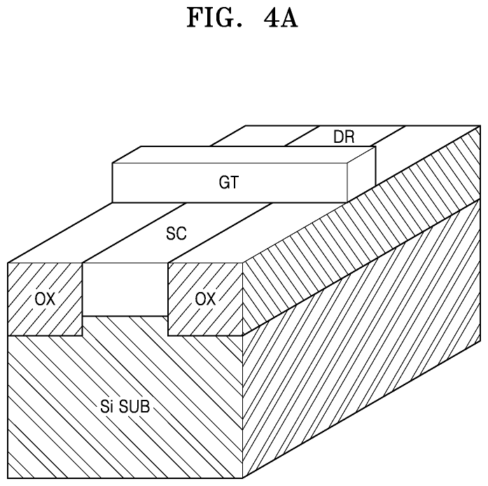

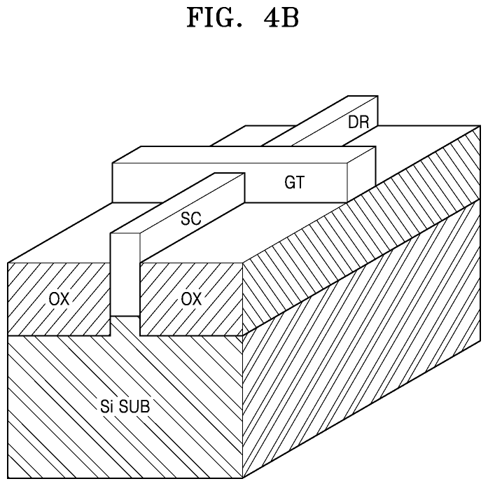

For example, when each of the plurality of transistors is a planar MOSCAP transistor, the pixel signal input terminal 132 may have a wider input range than that when including FinFET MOSCAP transistors. Characteristics of the ADC 130 according to a type of a transistor will be described in detail with reference to FIGS. 4A and 4B.

The ramp signal input terminal 133 according to an embodiment may receive a ramp signal RAMP compared with the pixel signal Pixel Input. The ramp signal input terminal 133 according to an embodiment may include at least one transistor, and the at least one transistor included in the ramp signal input terminal 133 may operate as a source follower that receives the ramp signal RAMP. The ramp signal input terminal 133 according to an embodiment may receive the ramp signal RAMP and may output the received ramp signal RAMP to the core amplifier 134.

The core amplifier 134 according to an embodiment may compare the pixel signal Pixel Input with the ramp signal RAMP, and may output the pixel signal Pixel Input based on a comparison result. For example, the core amplifier 134 may receive the pixel signal Pixel Input from the pixel signal input terminal 132, and may receive the ramp signal RAMP from the ramp signal input terminal 133. The core amplifier 134 according to an embodiment may compare the received pixel signal Pixel Input with the received ramp signal RAMP, and may output an amplified pixel signal based on a comparison result.

The core amplifier 134 according to an embodiment may include at least one comparator. The core amplifier 134 according to an embodiment may compare the pixel signal Pixel Input with the ramp signal RAMP by using the at least one comparator, and may amplify the pixel signal Pixel Input by using the at least one comparator.

The core amplifier 134 according to an embodiment may be initialized by an auto-zero switch. A plurality of auto-zero switches according to an embodiment may be located in the core amplifier 134. Also, the auto-zero switch according to an embodiment may be located outside the core amplifier 134 and may initialize the core amplifier 134. For example, the auto-zero switch may be connected in parallel to the at least one comparator located in the core amplifier 134, and when the auto-zero switch is closed, the at least one comparator may be discharged, to perform an initialization operation on the core amplifier 134.

FIG. 3 is a circuit diagram illustrating the ADC 130 of the image sensor 100, according to an embodiment.

Referring to FIG. 3, the ADC 130 according to an embodiment may receive an pixel signal Pixel Input from the pixel PX, and may generate an output signal CMP out. As described with reference to FIG. 2, the ADC 130 according to an embodiment may include pixel loads 131a and 131b, the pixel signal input terminal 132, the ramp signal input terminal 133, the core amplifier 134, or an auto-zero switching unit 134c.

Each of the pixel loads 131a and 131b according to an embodiment may include a pixel load switch SW_PL or a pixel load current source CR. When the pixel load switch SWL_PL is closed, the pixel load 131 according to an embodiment may receive the pixel signal Pixel Input. For example, when the pixel load switch SW_PL is closed, the pixel signal Pixel Input may be input to the ADC 130 by the pixel load current source CR. The pixel load current source CR according to an embodiment may be a passive current source, and may include a plurality of transistors. For example, the pixel load current source CR may include at least one planar transistor.

The pixel signal input terminal 132 according to an embodiment may include a multiplexer MUX, a first switch, or a pixel signal input transistor TR1. The pixel signal input terminal 132 according to an embodiment may be configured to receive a plurality of input signals. For example, the pixel signal input terminal 132 may include a plurality of input terminals, and each input terminal may be connected to at least one of the pixel loads 131a and 132b.

The multiplexer MUX according to an embodiment may operate as a switch, and may select any one of a plurality of pixel signals received from the pixel array 110. For example, the multiplexer MUX may be connected in series to each of the pixels PX of the pixel array 110, and may select the pixel signal Pixel Input.

The first switch SW1 according to an embodiment may be located in the pixel signal input terminal 132, and may control the pixel signal input terminal 132 to receive the pixel signal Pixel Input. For example, when the first switch SW1 is closed, the pixel signal input terminal 132 may receive the pixel signal Pixel Input selected by the multiplexer MUX. The pixel signal input transistor TR1 according to an embodiment may remove noise of a direct current (DC) component in the pixel signal Pixel Input, and may keep a waveform of the pixel signal Pixel Input in a stable state. For example, the pixel signal input transistor TR1 may perform the same operation as the capacitor and primarily remove noise from the pixel signal Pixel Input, to allow a waveform of the signal to have a certain shape.

The ramp signal input terminal 133 according to an embodiment may include an amplifier COMP and a ramp signal input transistor TR2, and may receive and output a ramp signal RAMP.

The amplifier COMP of the ramp signal input terminal 133 according to an embodiment may include at least one transistor. For example, the amplifier COMP of the ramp signal input terminal 133 may include at least one transistor and may operate as a source follower for the ramp signal RAMP. The amplifier COMP of the ramp signal input terminal 133 according to an embodiment may receive the ramp signal while operating as a source follower, and may output the received ramp signal RAMP through the ramp signal input transistor TR2. The ramp signal input transistor TR2 according to an embodiment may remove noise of a DC component in the ramp signal RAMP, and may keep a waveform of the ramp signal RAMP in a stable state. For example, the ramp signal input transistor TR2 may primarily remove noise from the ramp signal RAMP, to allow a waveform of the signal to have a certain shape.

The core amplifier 134 according to an embodiment may include a first comparator 134a, a second comparator 134b, and the auto-zero switching unit 134c.

The first comparator 134a according to an embodiment may be configured to compare the pixel signal Pixel Input with the ramp signal RAMP. The first comparator 134a according to an embodiment may include at least one transistor, may receive the pixel signal Pixel Input from the pixel signal input terminal 132, and may receive the ramp signal RAMP from the ramp signal input terminal 133. The first comparator 134a according to an embodiment may compare the received pixel signal Pixel Input with the received ramp signal RAMP, and may output the pixel signal Pixel Input to the second comparator 134b based on a comparison result. For example, the first comparator 134a may compare the received pixel signal Pixel Input with the received ramp signal RAMP, and when the received pixel signal Pixel Input is greater than the ramp signal RAMP as a comparison result, the first comparator 134a may output the pixel signal Pixel Input to the second comparator 134b.

The first comparator 134a according to an embodiment may be connected to a second switch SW2 for adjusting an input of the ramp signal RAMP. For example, the first comparator 134a may be connected in parallel to the second switch SW2, and when the second switch SW2 is closed, the ramp signal RAMP may be input to the first comparator 134a. The second switch SW2 according to an embodiment may be opened in an auto-zero period, to temporarily store an offset of the pixel signal Pixel Input in the pixel signal input transistor TR1.

Transistors included in the first comparator 134a according to an embodiment may be P-channel metal oxide semiconductor (PMOS) or N-channel metal oxide semiconductor (NMOS) transistors. When the transistors of the first comparator 134a according to an embodiment are PMOS transistors, the first comparator 134a may reduce thermal noise.

The second comparator 134b according to an embodiment may receive an output of the first comparator 134a, and may amplify the received output of the first comparator 134a. For example, the second comparator 134b may receive the pixel signal Pixel Input, may amplify the received pixel signal Pixel Input, and may generate the output signal CMP out.

The second comparator 134b according to an embodiment may include at least one transistor. The second comparator 134b according to an embodiment may receive an output of the first comparator 134a through a PMOS transistor. When the output of the first comparator 134a is received through the PMOS transistor, the second comparator 134b according to an embodiment may reduce thermal noise.

The second comparator 134b according to an embodiment may output the output signal CMP out through an NMOS transistor. When the output signal CMP out is output through the NMOS transistor, the second comparator 134b according to an embodiment may reduce generated noise.

The auto-zero switching unit 134c according to an embodiment may be configured to perform an initialization operation on the core amplifier 134. The auto-zero switching unit 134c according to an embodiment may include a third switch SW3, a fourth switch SW4, or an auto-zero transistor TR3. The third switch SW3, the fourth switch SW4, and the auto-zero transistor TR3 according to an embodiment may include planar transistors. When the third switch SW3, the fourth switch SW4, and the auto-zero transistor TR3 include planar transistors, the auto-zero switching unit 134c according to an embodiment may reduce leakage current, and may perform an efficient initialization operation on the core amplifier 134.

The third switch SW3 according to an embodiment may be opened in an auto-zero period, to temporarily store an offset of the ramp signal RAMP in the ramp signal input transistor TR2. When the third switch SW3 according to an embodiment is closed, the pixel signal input transistor TR1 and the ramp signal input transistor TR2 may be discharged and initialized.

FIG. 4A is a view for describing a planar transistor, according to an embodiment. FIG. 4B is a view for describing a FinFET, according to an embodiment.

Referring to FIGS. 4A and 4B, each of a planar transistor and a FinFET according to an embodiment may include a silicon layer region Si SUB, an oxide region OX, a source region SC, a gate region GT, or a drain region DR.

Referring to FIG. 4A, in the planar transistor according to an embodiment, the gate region GT, and the source region SC and the drain region DR may contact each other by one plane. In the planar transistor according to an embodiment, because the gate region GT contacts the source region SC and the drain region DR through one plane, the area that may be controlled by the gate region GT is less than that in the FinFET described below. In the planar transistor according to an embodiment, because the gate region GT, and the source region SC and the drain region DR contact each other by one plane, generation of thermal noise is less than that in the FinFET.

Referring to FIG. 4B, in the FinFET according to an embodiment, the gate region GT, and the source region SC and the drain region DR may contact each other by three planes. In the FinFET according to an embodiment, because the gate region GT contacts the source region SC and the drain region DR through three planes, the area that may be controlled by the gate region GT is greater than that in the planar transistor. In the FinFET according to an embodiment, because the gate region GT, and the source region SC and the drain region DR contact each other by three planes, generation of thermal noise is greater than that in the planar transistor.

Referring back to FIGS. 4A and 4B, when one or more transistors of a plurality of transistors included in the ADC 130 are planar transistors, the ADC 130 may have less thermal noise than that when including FinFETs.

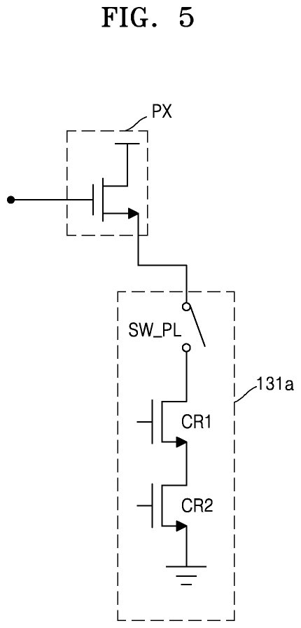

FIG. 5 is a circuit diagram for describing the pixel load 131 of an image sensor, according to an embodiment.

The pixel load 131 according to an embodiment may include a pixel load switch SW_PL, a first pixel load transistor CR1, or a second pixel load transistor CR2. The first pixel load transistor CR1 or the second pixel load transistor CR2 may be the pixel load current source CR of FIG. 3. When the pixel load switch SW_PL is closed, the pixel load 131 according to an embodiment may receive a pixel signal Pixel Input. For example, when the pixel load switch SW_PL is closed, the pixel signal Pixel Input may be input to the ADC 130 by the first pixel load transistor CR1 or the second pixel load transistor CR2. The first pixel load transistor CR1 or the second pixel load transistor CR2 according to an embodiment may constitute a passive current source, and may further include a plurality of transistors.

The first pixel load transistor CR1 or the second pixel load transistor CR2 according to an embodiment may include a planar transistor. When the first pixel load transistor CR1 or the second pixel load transistor CR2 includes a planar transistor, the ADC 130 according to an embodiment may reduce thermal noise.

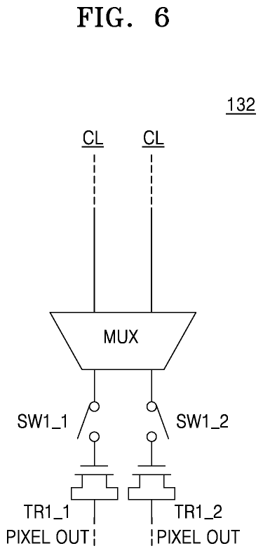

FIG. 6 is a circuit diagram for describing the pixel signal input terminal 132 of an image sensor, according to an embodiment.

Referring to FIG. 6, the pixel signal input terminal 132 according to an embodiment may include a multiplexer MUX, a first input terminal switch SW1_1, a second input terminal switch SW1_2, or pixel signal input transistors TR1_1 and TR1_2.

The multiplexer MUX according to an embodiment may operate as a switch, and may select any one of a plurality of pixel signals received from the pixel array 110. For example, the multiplexer MUX may be connected in series to the pixels PX included in the pixel array 110 through the column lines CL, and may select a pixel signal Pixel Input.

Referring to FIG. 6, the multiplexer MUX according to an embodiment may be shared by a plurality of core amplifiers. For example, the first input terminal switch SW1_1 may be located in the pixel signal input terminal 132, and may control the pixel signal input terminal 132 so that a first core receives the pixel signal Pixel Input. The first input terminal switch SW1_1 according to an embodiment may include a planar transistor. When the first input terminal switch SW1_1 includes a planar transistor, the ADC 130 according to an embodiment may reduce thermal noise.

The first pixel signal input transistor TR1_1 according to an embodiment may temporarily store an offset of the received pixel signal Pixel Input. The first pixel signal input transistor TR1_1 according to an embodiment may include a planar transistor. When the first pixel signal input transistor TR1_1 includes a planar transistor, the ADC 130 according to an embodiment may reduce thermal noise.

Also, the second input terminal switch SW1_2 according to an embodiment may be located in the pixel signal input terminal 132, and may control the pixel signal input terminal 132 so that a second core amplifier receives the pixel signal Pixel Input. The second input terminal switch SW1_2 according to an embodiment may include a planar transistor. When the second input terminal switch SW1_2 includes a planar transistor, the ADC 130 according to an embodiment may reduce thermal noise.

The second pixel signal input transistor TR1_2 according to an embodiment may temporarily store an offset of the received pixel signal Pixel Input. The second pixel signal input transistor TR1_2 according to an embodiment may include a planar transistor. When the second pixel signal input transistor TR1_2 includes a planar transistor, the ADC 130 according to an embodiment may reduce thermal noise.

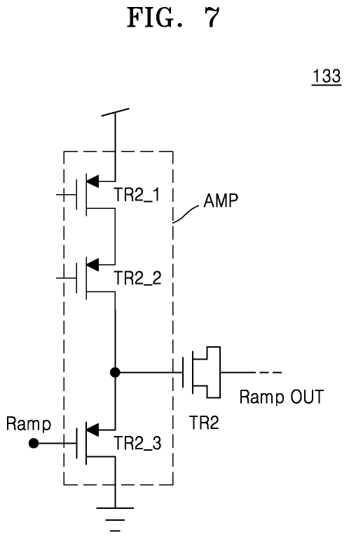

FIG. 7 is a circuit diagram for describing a ramp signal input terminal of an image sensor, according to an embodiment.

Referring to FIG. 7, the ramp signal input terminal 133 according to an embodiment may include an amplifier AMP and a ramp signal input transistor TR2, and may receive a ramp signal RAMP and may output a ramp output signal Ramp OUT. The amplifier AMP according to an embodiment may include a first amplifier transistor TR2_1, a second amplifier transistor TR2_2, or a third amplifier transistor TR2_3.

For example, in the ramp signal input terminal 133, the amplifier AMP may include a first amplifier transistor TR2_1, a second amplifier transistor TR2_2, or a third amplifier transistor TR2_3, and may operate as a source follower for the ramp signal RAMP. The first amplifier transistor TR2_1, the second amplifier transistor TR2_2, or the third amplifier transistor TR2_3 of the ramp signal input terminal 1333 may operate as a source follower, and may receive the ramp signal and may output the received ramp signal RAMP through the ramp signal input transistor TR2.

The first amplifier transistor TR2_1, the second amplifier transistor TR2_2, or the third amplifier transistor TR2_3 may include a planar transistor. When the first amplifier transistor TR2_1, the second amplifier transistor TR2_2, or the third amplifier transistor TR2_3 includes a planar transistor, the ramp signal input terminal 133 according to an embodiment may reduce generation of thermal noise.

The third amplifier transistor TR2_3 according to an embodiment may include a FinFET. When the third amplifier transistor TR2_3 includes a FinFET, a higher input range than that when the third amplifier transistor TR2_3 includes a planar transistor may be ensured. Also, when the third amplifier transistor TR2_3 includes a FinFET, a volume of the ramp signal input terminal 133 may be less than that when the third amplifier transistor TR2_3 includes a planar transistor.

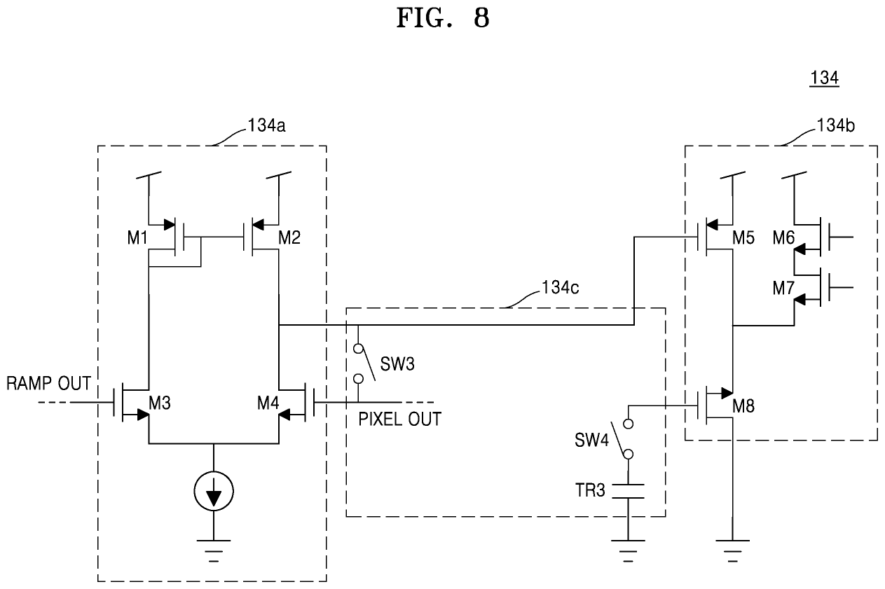

FIG. 8 is a circuit diagram for describing a core amplifier of an image sensor, according to an embodiment.

Referring to FIG. 8, the first comparator 134a according to an embodiment may be configured to compare a pixel signal Pixel Input with a ramp signal RAMP. The first comparator 134a according to an embodiment may include a first transistor M1, a second transistor M2, a ramp signal input transistor M3, or a pixel signal input transistor M4.

The first comparator 134a according to an embodiment may compare the received pixel signal Pixel Input with the received ramp signal RAMP through the first transistor M1 and the second transistor M2, and may output the pixel signal Pixel Input to the second comparator 134b based on a comparison result. For example, the first comparator 134a may compare the pixel signal Pixel Input received by the pixel signal input transistor M4 with the ramp signal RAMP received by the ramp signal input transistor M3, and when the received pixel signal Pixel Input is greater than the ramp signal RAMP as a comparison result, the first comparator 134a may output the pixel signal Pixel Input to the second comparator 134b.

The first transistor M1, the second transistor M2, the ramp signal input transistor M3, or the pixel signal input transistor M4 of the first comparator 134a may include a planar transistor. Also, the ramp signal input transistor M3 or the pixel signal input transistor M4 may include a FinFET. When the first transistor M1, the second transistor M2, the ramp signal input transistor M3, or the pixel signal input transistor M4 of the first comparator 134a includes a planar transistor, the ADC 130 according to an embodiment may reduce generation of thermal noise.

The second comparator 134b according to an embodiment may include a third transistor M5, a fourth transistor M8, or amplification transistors M6 and M7.

For example, the third transistor M5 may receive the pixel signal Pixel Input, and the amplification transistors M6 and M7 may generate an output signal CMP out by keeping constant the received pixel signal Pixel Input. The fourth transistor M8 according to an embodiment may output the output signal CMP out as an output signal of the ADC 130.

The third transistor M5 according to an embodiment may be a PMOS transistor. When the third transistor is a PMOS transistor, the second comparator 134b according to an embodiment may reduce thermal noise. The fourth transistor M8 according to an embodiment may be an NMOS transistor. When the fourth transistor M8 is an NMOS transistor, the second comparator 134b according to an embodiment may reduce generated noise.

The third transistor M5, the fourth transistor M8, or the amplification transistors M6 and M7 of the second comparator 134b may include planar transistors. Also, the amplification transistors M6 and M7 according to an embodiment may include FinFETs. When the third transistor M5, the fourth transistor M8, or the amplification transistors M6 and M7 of the second comparator 134b include planar transistors, the ADC 130 according to an embodiment may reduce generation of thermal noise. For example, FinFET has a high surface area for the same area, so it can have high gain, and has a high current driving ability, so it has the advantage of fast speed. Therefore, transistors that require high gain and fast speed may include FinFETs, and transistors that need to reduce thermal noise may include planar transistors.

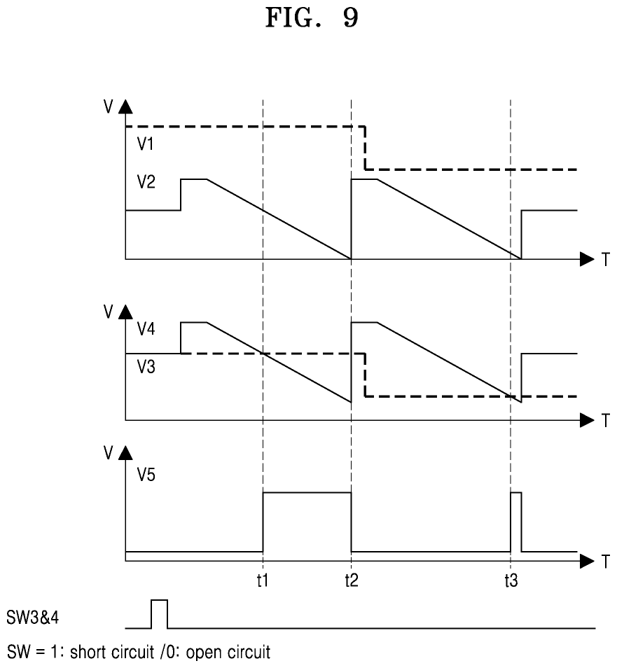

FIG. 9 is a timing diagram for describing a method of operating an image sensor, according to an embodiment.

Referring to FIG. 9, a pixel signal according to an embodiment may be input as a first voltage value V1 to the pixel signal input terminal 132, and a ramp signal may be input as a second voltage value V2 to the ramp signal input terminal 133. The pixel signal may be input as a third voltage value V3 to the core amplifier 134 according to an embodiment, and the ramp signal RAMP may be input as a fourth voltage value V4 to the core amplifier 134. Also, an output signal CMPout according to an embodiment may have a fifth voltage value V5.

The third switch SW3 or the fourth switch SW4 according to an embodiment may initialize the core amplifier 134, and may receive the ramp signal RAMP and the pixel signal Pixel Input. The ADC 130 according to an embodiment may compare the pixel signal having the third voltage value V3 with the ramp signal having the fourth voltage value V4 at a first time point t1, and may generate the output signal CMPout until a second time point t2 when the third voltage value V3 is greater than the fourth voltage value V4.

When elements of the ADC 130 include at least one planar transistor, the ADC 130 according to an embodiment may have low thermal noise, and as a result, may generate the output signal CMPout even in a period where a difference between the third voltage value V3 and the fourth voltage value V4 is not large, such as in a third time point t3.

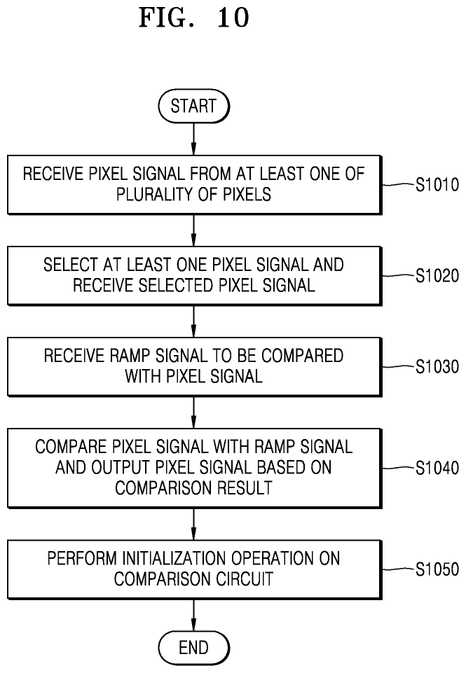

FIG. 10 is a flowchart for describing a method of operating an image sensor, according to an embodiment.

Referring to FIG. 10, the ADC 130 according to an embodiment may receive a pixel signal from at least one of a plurality of pixels (S1010).

The ADC 130 of the image sensor 100 according to an embodiment may include the pixel load switch SWL_PL or the pixel load current source CR. When the pixel load switch SW_PL is closed, the ADC 130 of the image sensor 100 according to an embodiment may receive a pixel signal Pixel Input. For example, when the pixel load switch SW_PL is closed, the pixel signal Pixel Input may be input to the ADC 130 by the pixel load current source CR. The pixel load current source CR according to an embodiment may be a passive current source, and may include a plurality of transistors. For example, the pixel load current source CR may include at least one planar transistor.

When a pixel signal is received from at least one of the plurality of pixels, the ADC 130 of the image sensor 100 according to an embodiment may select at least one pixel signal, and may receive the selected pixel signal (S1020).

The ADC 130 of the image sensor 100 according to an embodiment may include the multiplexer MUX, the first switch, or the pixel signal input transistor TR1. The multiplexer MUX according to an embodiment may operate as a switch, and may select any one of a plurality of pixel signals received from the pixel array 110. For example, the multiplexer MUX may be connected in series to the pixels PX included in the pixel array 110, and may select the pixel signal Pixel Input. The first switch SW1 according to an embodiment may receive the pixel signal Pixel Input. When the first switch SW1 is closed, the ADC 130 of the image sensor 100 according to an embodiment may receive the pixel signal Pixel Input selected by the multiplexer MUX. The pixel signal input transistor TR1 according to an embodiment may convert the received analog signal into a digital signal. For example, the pixel signal input transistor TR1 may primarily remove noise from the pixel signal Pixel Input, to allow a waveform of the signal to have a certain shape.

The ADC 130 of the image sensor 100 according to an embodiment may receive a ramp signal compared with the pixel signal (S1030).

The amplifier COMP of the ADC 130 of the image sensor 100 may include at least one transistor, and may receive the ramp signal. For example, the amplifier COMP of the ADC 130 of the image sensor 100 may include at least one transistor, and may operate as a source follower for the ramp signal RAMP. For example, a transistor included in the amplifier COMP may be connected to a source line, and the ramp signal input terminal 133 may operate as a source follower. The amplifier COMP of the ADC 130 of the image sensor 100 according to an embodiment may operate as a source follower, and may output the received ramp signal RAMP through the ramp signal input transistor TR2. The ramp signal input transistor TR2 according to an embodiment may convert the received analog signal into a digital signal. For example, the ramp signal input transistor TR2 may primarily remove noise from the ramp signal RAMP, to allow a waveform of the signal to have a certain shape.

When the pixel signal and the ramp signal are input, the ADC 130 of the image sensor 100 according to an embodiment may compare the pixel signal with the ramp signal, and may output an output signal CMPout based on a comparison result (S1040).

The ADC 130 of the image sensor 100 according to an embodiment may be configured to compare the pixel signal Pixel Input with the ramp signal RAMP. The ADC 130 of the image sensor 100 according to an embodiment may include at least one transistor, and may receive the pixel signal Pixel Input and may receive the ramp signal RAMP. The ADC 130 of the image sensor 100 according to an embodiment may compare the received pixel signal Pixel Input with the received ramp signal RAMP, and may output the output signal CMP out based on a comparison result. For example, the ADC 130 of the image sensor 100 may compare the received pixel signal Pixel Input with the ramp signal RAMP, and when the pixel signal Pixel Input is greater than the ramp signal RAMP as a comparison result, may generate the output signal CMP out.

When the output signal CMP out is generated, the ADC 130 of the image sensor 100 may perform an initialization operation on a comparison circuit (S1050).

The ADC 130 of the image sensor 100 according to an embodiment may perform an initialization operation the first comparator 134a of the core amplifier 134. For example, the ADC 130 of the image sensor 100 may discharge and initialize the first comparator 134a. The ADC 130 of the image sensor 100 according to an embodiment may perform an initialization operation on the second comparator 134b of the core amplifier 134. For example, the ADC 130 of the image sensor 100 may discharge and initialize the second comparator 134b.

While example embodiments have been particularly shown and described, it will be understood by one of ordinary skill in the art that various changes in form and details may be made therein without departing from the spirit and scope of the disclosure. Accordingly, the embodiments should be considered in descriptive sense only and not for purposes of limitation. The scope of the disclosure is not limited by the example embodiments but by the appended claims, and all differences within the scope will be construed as being included in the disclosure.

1. An analog-to-digital converter of an image sensor, the analog-to-digital converter comprising:
a pixel load connected to a column line connected to a plurality of pixels;
a pixel signal input terminal configured to receive a pixel signal through the column line;
a ramp signal input terminal configured to receive a ramp;
a core amplifier configured to compare the pixel signal with the ramp signal, and output the pixel signal based on a comparison result; and
an auto-zero switching unit configured to initialize the core amplifier,
wherein the core amplifier comprises:
a first comparator configured to compare the pixel signal with the ramp signal, the first comparator comprising a first transistor and a second transistor; and
a second comparator comprising a third transistor configured to receive an output signal of the first comparator and a fourth transistor configured to amplify the output signal,
wherein the first comparator is further configured to receive the pixel signal or the ramp signal through a fin field-effect transistor (FinFET), and
wherein each of the first transistor, the second transistor, the third transistor, and the fourth transistor comprises a planar transistor.

2. The analog-to-digital converter of claim 1, wherein the pixel load comprises a current source comprising at least one planar transistor.

3. The analog-to-digital converter of claim 1, wherein the pixel signal input terminal comprises:
a multiplexer connected to a plurality of column lines, and configured to connect the plurality of column lines to a plurality of output lines; and
a first switch connected to each of the plurality of output lines, and comprising a planar transistor.

4. The analog-to-digital converter of claim 1, wherein the source follower comprises a planar transistor.

5. The analog-to-digital converter of claim 1, wherein each of the first transistor and the second transistor is P-channel metal oxide semiconductor (PMOS) transistor.

6. The analog-to-digital converter of claim 1, wherein the third transistor is a is P-channel metal oxide semiconductor (PMOS) transistor.

7. The analog-to-digital converter of claim 1, wherein the fourth transistor is an N-channel metal oxide semiconductor (NMOS) transistor.

8. The analog-to-digital converter of claim 1, wherein the first comparator of the core amplifier is connected to a second switch for adjusting an input of the ramp signal.

9. The analog-to-digital converter of claim 1, wherein the auto-zero switching unit comprises:
a third switch configured to perform a first initialization operation on the first comparator of the core amplifier; and
a fourth switch configured to perform a second initialization operation on the first comparator of the core amplifier.

10. The analog-to-digital converter of claim 9, wherein each of the third switch and the fourth switch comprises a planar transistor.

11. An image sensor comprising:
a pixel array connected to a plurality of column lines and comprising a plurality of pixels; and
an analog-to-digital converter configured to convert a plurality of pixel signals output through the plurality of column lines,
wherein the analog-to-digital converter comprises:
a pixel load configured to receive a pixel signal from at least one of the plurality of pixels,
a pixel signal input terminal configured to select at least one pixel signal, and receive the selected at least one pixel signal,
a ramp signal input terminal configured to receive a ramp signal,
a core amplifier configured to compare the pixel signal with the ramp signal, and output the pixel signal based on a comparison result, and
an auto-zero switching unit configured to perform an initialization operation on the core amplifier,
wherein the core amplifier comprises:
a first comparator comprising a first transistor and a second transistor configured to compare the pixel signal with the ramp signal, and
a second comparator comprising a third transistor configured to receive an output signal of the first comparator and a fourth transistor configured to amplify the output signal,
wherein the first comparator is further configured to receive the pixel signal or the ramp signal through a fin field-effect transistor (FinFET), and
wherein each of the first transistor, the second transistor, the third transistor, and the fourth transistor comprises a planar transistor.

12. The image sensor of claim 11, wherein the pixel load comprises a current source comprising at least one planar transistor.

13. The image sensor of claim 11, wherein the pixel signal input terminal comprises a multiplexer connected in series to at least one of the plurality of pixels, and configured to receive the at least one pixel signal received from at least one pixel, and
wherein the multiplexer comprises a first switch comprising at least one planar transistor.

14. The image sensor of claim 11, wherein the source follower comprises a planar transistor.

15. The image sensor of claim 11, wherein each of the first transistor and the second transistor is P-channel metal oxide semiconductor (PMOS) transistors.

16. The image sensor of claim 11, wherein the third transistor is a P-channel metal oxide semiconductor (PMOS) transistor.

17. The image sensor of claim 11, wherein the fourth transistor is an N-channel metal oxide semiconductor (NMOS) transistor.

18. The image sensor of claim 11, wherein the first comparator is connected to a second switch for adjusting an input of the ramp signal.

19. The image sensor of claim 11, wherein the auto-zero switching unit comprises:
a third switch configured to perform a first initialization operation on the first comparator; and
a fourth switch configured to perform a second initialization operation on the second comparator.

20. (canceled)

21. A core amplifier of an analog-to-digital converter of an image sensor, the core amplifier comprising:
a first comparator configured to compare a pixel signal with a ramp signal, the first comparator comprising a first transistor and a second transistor; and
a second comparator comprising a third transistor configured to receive an output signal of the first comparator and a fourth transistor configured to amplify the output signal,
wherein the first comparator is further configured to receive the pixel signal or the ramp signal through a fin field-effect transistor (FinFET), and
wherein each of the first transistor, the second transistor, the third transistor, and the fourth transistor comprises a planar transistor.
